(19) United States
(12) Patent Application Publication
(10) Pub. No.: US 2023/0138471 A1
(43) Pub. Date: May 4, 2023

(54) DYNAMIC NEGATIVE CHARGE PUMP FOR NON-VOLATILE MEMORY

(71) Applicant: Intel NDTM US LLC, Santa Clara, CA (US)

(72) Inventors: Binh Ngo, Folsom, CA (US); Moonkyun Maeng, Sacramento, CA (US); Navid Paydavosi, Seattle, WA (US); Sagar Upadhyay, Folsom, CA (US); Sanket Sanjay Wadyalkar, Folsom, CA (US); Soo-yong Park, San Jose, CA (US)

(73) Assignee: Intel NDTM US LLC, Santa Clara, CA (US)

(21) Appl. No.: 18/089,422

(22) Filed: Dec. 27, 2022

(51) Int. Cl. G11C 16/30; G11C 16/04; G11C 16/26; G11C 16/34

(52) U.S. Cl. CPC G11C 16/30; G11C 16/0483; G11C 16/26; G11C 16/3459

(57) ABSTRACT

An example of an apparatus may include NAND memory and circuitry coupled to the NAND memory to monitor a sense voltage for an operation associated with a wordline of the NAND memory, and adjust a negative charge pump for the wordline prior to completion of the operation based on the monitored sense voltage. Other examples are disclosed and claimed.

### BACKGROUND

A direct current (DC)-to-DC converter that uses capacitors for charge storage to raise or lower voltage may be referred to as a charge pump. Flash memories are used in many electronic devices. In a flash memory, voltages that are higher than supply voltages may be utilized for various programming operations. In many cases, such programming voltages are generated by charge pumps. Different charge pumps with different voltage characteristics are utilized for various operations of the memory cell. For example, positive charge pumps may provide the needed positive voltages for the wordlines (WLs) of the memory cell array, and negative charge pumps may be utilized to provide the needed negative WL voltages.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is a block diagram of an apparatus, according to an example;

FIG. 2 is a block diagram of a memory device, according to an example;

FIG. 3 is a block diagram of a system, according to an example;

FIGS. 4A to 4C are illustrative diagrams of a NAND die according to an example;

FIGS. 5A to 5C are illustrative diagrams of independent multi-plane operations according to examples;

FIG. 6 is a block diagram of another system according to an example;

FIG. 7 is an illustrative diagram of voltage signals for a dynamic negative charge pump configuration according to an example; and

FIG. 8 is another illustrative diagram of voltage signals for a dynamic negative charge pump configuration according to an example.

### DETAILED DESCRIPTION

One or more examples or implementations are now described with reference to the enclosed figures. While specific configurations and arrangements are discussed, it should be understood that this is done for illustrative purposes only. Persons skilled in the relevant art will recognize that other configurations and arrangements may be employed without departing from the spirit and scope of the description. It will be apparent to those skilled in the relevant art that techniques and/or arrangements described herein may also be employed in a variety of other systems and applications other than what is described herein.

While the following description sets forth various implementations that may be manifested in architectures such as system-on-a-chip (SoC) architectures for example, implementation of the techniques and/or arrangements described herein are not restricted to particular architectures and/or computing systems and may be implemented by any architecture and/or computing system for similar purposes. For instance, various architectures employing, for example, multiple integrated circuit (IC) chips and/or packages, and/or various computing devices and/or consumer electronic (CE) devices such as set top boxes, smartphones, etc., may implement the techniques and/or arrangements described herein. Further, while the following description may set forth numerous specific details such as logic implementations, types and interrelationships of system components, logic partitioning/integration choices, etc., claimed subject matter may be practiced without such specific details. In other instances, some material such as, for example, control structures and full software instruction sequences, may not be shown in detail in order not to obscure the material disclosed herein.

The material disclosed herein may be implemented in hardware, Field Programmable Gate Array (FPGA), firmware, driver, software, or any combination thereof. The material disclosed herein may also be implemented as instructions stored on a machine-readable medium, that may be read and executed by Moore Machine, Mealy Machine, and/or one or more processors. A machine-readable medium may include any medium and/or mechanism for storing or transmitting information in a form readable by a machine (e.g., a computing device). For example, a machine-readable medium may include read only memory (ROM); random access memory (RAM); Dynamic random-access memory (DRAM), magnetic disk storage media; optical storage media; non-volatile (NV) memory devices; qubit solid-state quantum memory, electrical, optical, acoustical or other forms of propagated signals (e.g., carrier waves, infrared signals, digital signals, etc.), and others.

References in the specification to “one implementation”, “an implementation”, “an example implementation”, etc., indicate that the implementation described may include a particular feature, structure, or characteristic, but every example may not necessarily include the particular feature, structure, or characteristic. Moreover, such phrases are not necessarily referring to the same implementation. Further, when a particular feature, structure, or characteristic is described in connection with an example, it is submitted that it is within the knowledge of one skilled in the art to effect such feature, structure, or characteristic in connection with other implementations whether or not explicitly described herein.

NV memory (NVM) may be a storage medium that does not require power to maintain the state of data stored by the medium. In one example, the memory device may include a three-dimensional (3D) NAND device. The memory device may refer to the die itself and/or to a packaged memory product. In particular examples, a memory component with non-volatile memory may comply with one or more standards promulgated by the JEDEC, or other suitable standard (the JEDEC standards cited herein are available at jedec.org). A problem is that, as NVM devices scale to higher densities and/or higher performance, the power usage also scales up (e.g., with higher energy-per-bit metrics). NVM devices may include a number of positive and negative charge pumps that may be utilized to provide various voltages during various operations of the NVM device. A problem is that a negative charge pump may be on during some operations where the negative voltage provided by the negative charge pump is not needed at all, unnecessarily consuming energy and/or degrading an amount of energy-per-bit. Another problem is that the negative charge pump may be kept on during some operations after the negative voltage provided by the negative charge pump is no longer needed, unnecessarily consuming energy and/or degrading an amount of energy-per-bit. Some examples may overcome one or more of the foregoing problems.

Some examples provide technology for a dynamic negative charge pump configuration. In some examples, suitable circuitry may actively monitor the read/program-verify sense voltage and adjust the negative charge pump responsible to supply the negative WL voltage during the read and program operations. For example, the negative charge pump may only be needed when a threshold voltage (Vt) is in a negative range. Some examples may monitor an operation and turn off the negative charge pump if Vt for the monitored operation is in a positive range. Advantageously, some examples may significantly improve power usage (e.g., reduce power consumption) during read and/or program operations of a flash memory device. Some examples provide technology that dynamically configures a negative charge pump based on the read and program verify sense voltages during an independent multi-plane operation (IMPO) (e.g., a program operation, an independent multi-plane read operation (IMPRO), etc.), advantageously improving IMPO and/or IMPRO operation power usage (e.g., energy-per-bit) for the memory device.

In some examples, one or more trim threshold voltages may be set to indicate whether or not the negative charge pump is needed. The trim threshold(s) may be adjusted as needed. In some examples, different trim threshold voltage values may be utilized for different operations (e.g., a first trim threshold voltage value for read operations and a second trim threshold voltage value for program-verify operations).

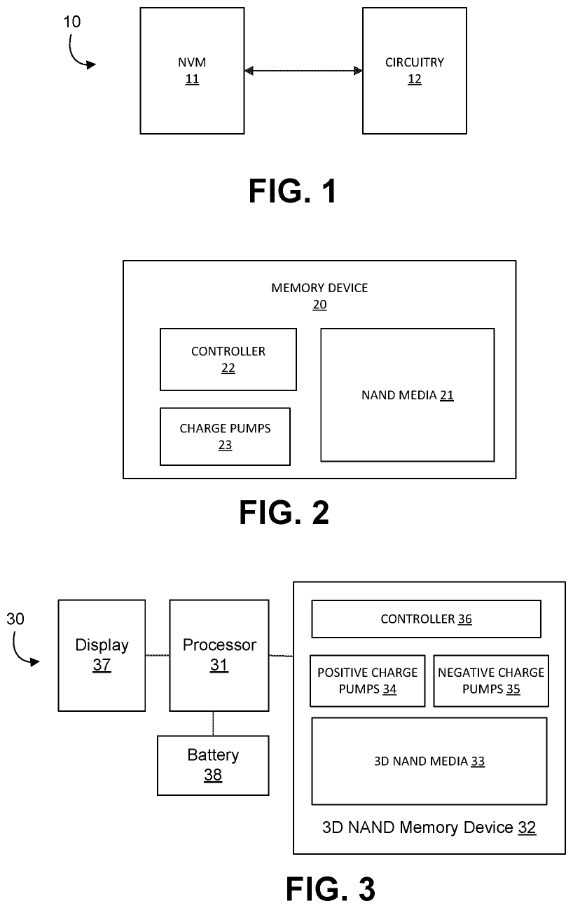

FIG. 1 shows an example of an apparatus 10 that includes NVM memory 11 (e.g., NAND memory, 3D NAND memory, etc.), and circuitry 12 coupled to the NVM memory to monitor a sense voltage for an operation associated with a wordline of the NVM memory 11, and adjust a negative charge pump for the wordline prior to completion of the operation (e.g., during the operation) based on the monitored sense voltage. For example, the circuitry 12 may be configured to adjust the negative charge pump for the wordline based on a comparison of the monitored sense voltage and a trim threshold voltage value. In some examples, the circuitry 12 may be further configured to turn on the negative charge pump if the monitored sense voltage is less than the trim threshold voltage value, and turn off the negative charge pump when the monitored sense voltage is greater than or equal to the trim threshold voltage value.

In some examples, the circuitry 12 may be configured to compare the monitored sense voltage for a read operation against an adjustable trim voltage value, turn on the negative charge pump at a start of the read operation if the monitored sense voltage is less than the adjustable trim voltage value, and turn off the negative charge pump prior to completion of the read operation (e.g., at any point of the read operation) if the monitored sense voltage is greater than or equal to the adjustable trim voltage value. For example, the circuitry 12 may be configured to adjust the adjustable trim voltage value based on a lowest positive threshold voltage (Vt) level for the read operation.

In some examples, the circuitry 12 may be configured to compare the monitored sense voltage at a start of a program verify operation against another adjustable trim voltage value (e.g., that may be different from the adjustable trim voltage value for the read operation) turn on the negative charge pump if the monitored sense voltage at the start of the program verify operation is less than the adjustable trim voltage value, and turn off the negative charge pump if the monitored sense voltage at the start of the program verify operation is greater than or equal to the adjustable trim voltage value. For example, the circuitry 12 may be configured to adjust the adjustable trim voltage value based on a lowest positive target threshold voltage (Vt) level for the program verify operation.

FIG. 2 shows an example of a memory device 20 that includes NAND media 21, a controller 22 to control access to the NAND media 21 (e.g. 3D NAND media), and charge pumps 23 (e.g., including positive charge pumps and negative charge pumps) coupled to the NAND media 21. The controller 23 may be coupled to the NAND media 21 and the charge pumps 23, and configured to set a trim threshold voltage value, monitor a voltage for a sense operation associated with a wordline of the NAND media 21, and turn a negative charge pump for the sense operation one of on and off based on a comparison of the monitored voltage and the trim threshold voltage value. For example, the controller 22 may be configured to turn on the negative charge pump if the monitored voltage is less than the trim threshold voltage value, and turn off the negative charge pump when the monitored sense voltage is greater than or equal to the trim threshold voltage value.

In some examples, the controller 22 may be further configured to set the trim threshold voltage value for a read operation based on a lowest positive threshold voltage (Vt) level for the read operation. For example, the controller 22 may be configured to turn on the negative charge pump at a start of the read operation if the monitored voltage is less than the trim threshold voltage value, and turn off the negative charge pump prior to completion of the read operation if the monitored voltage is greater than or equal to the trim threshold voltage value.

In some examples, the controller 22 may be further configured to set the trim threshold voltage value based on a lowest positive target threshold voltage (Vt) level for a program verify operation. For example, the controller 22 may be configured to turn on the negative charge pump if the monitored voltage at a start of the program verify operation is less than the trim threshold voltage value, and turn off the negative charge pump if the monitored voltage at the start of the program verify operation is greater than or equal to the trim threshold voltage value.

FIG. 3 shows an example of a system 30 that includes a processor 31 and a 3D NAND memory device 32 coupled to the processor. In some examples, the 3D NAND memory device 32 may be similarly configured as the various examples described herein (e.g., the apparatus 10, the memory device 20, the memory device 61, etc.). The 3D NAND memory device 32 may include 3D NAND media 33, a plurality of positive charge pumps 34 respectively coupled to wordlines of the 3D NAND media 33, a plurality of negative charge pumps 35 respectively coupled to wordlines of the 3D NAND media 33, and a controller 36 to control access to the NAND media 33. The controller 36 may be configured to set an adjustable trim voltage value, monitor a voltage for a sense operation associated with a wordline of the 3D NAND media 33, and turn a negative charge pump for the sense operation one of on and off based on a comparison of the monitored voltage and the adjustable trim voltage value. For example, the controller 36 may be further configured to turn on the negative charge pump if the monitored voltage is less than the adjustable trim voltage value, and turn off the negative charge pump when the monitored sense voltage is greater than or equal to the adjustable trim voltage value.

In some examples, the controller 36 may be configured to set the trim threshold voltage value for a read operation based on a lowest positive threshold voltage (Vt) level for the read operation. For example, the controller 36 may be further configured to turn on the negative charge pump at a start of the read operation if the monitored voltage is less than the adjustable trim voltage value, and turn off the negative charge pump prior to completion of the read operation if the monitored voltage is greater than or equal to the adjustable trim voltage value.

In some examples, the controller 36 may be configured to set the adjustable trim voltage value based on a lowest positive target threshold voltage (Vt) level for a program verify operation. For example, the controller 36 may be further configured to turn on the negative charge pump if the monitored voltage at a start of the program verify operation is less than the adjustable trim voltage value, and turn off the negative charge pump if the monitored voltage at the start of the program verify operation is greater than or equal to the adjustable trim voltage value.

The processor 31 may include or be communicatively coupled to one or more of a general purpose controller, a special purpose controller, a memory controller, a storage controller, a micro-controller, an execution unit, etc. In some examples, the NAND media 33, the charge pumps 34, 35, the controller 36, and/or other system memory may be located in, or co-located with, various components, including the processor 31 (e.g., on a same die or package substrate). For example, the processor 31 may include a memory controller and be implemented as a connected memory device such as a memory module, a non-volatile dual-inline memory module (NVDIMM), a solid-state drive (SSD), a memory node, etc. The processor 31 may be further coupled to additional components or peripheral devices such as a display 37, a battery 38, etc.

Examples of a suitable processor and each of the above NAND media 33, charge pumps 34, 35, controller 36, and other system components may be implemented in hardware, software, or any suitable combination thereof. For example, hardware implementations may include configurable logic, fixed-functionality logic, or any combination thereof. Examples of configurable logic include suitably configured programmable logic arrays (PLAs), FPGAs, complex programmable logic devices (CPLDs), and general purpose microprocessors. Examples of fixed-functionality logic include suitably configured application specific integrated circuits (ASICs), combinational logic circuits, and sequential logic circuits. The configurable or fixed-functionality logic may be implemented with complementary metal oxide semiconductor (CMOS) logic circuits, transistor-transistor logic (TTL) logic circuits, or other circuits.

For example, the controller may be implemented with circuitry on a semiconductor apparatus, that may include one or more substrates, with the circuitry coupled to the one or more substrates. In some examples, the circuitry may be at least partly implemented in one or more of configurable logic and fixed-functionality hardware logic on semiconductor substrate(s) (e.g., silicon, sapphire, gallium-arsenide, etc.). For example, the circuitry may include a transistor array and/or other integrated circuit components coupled to the substrate(s) with transistor channel regions that are positioned within the substrate(s). The interface between the circuitry and the substrate(s) may not be an abrupt junction. The circuitry may also be considered to include an epitaxial layer that is grown on an initial wafer of the substrate(s).

Alternatively, or additionally, all or portions of these components may be implemented in one or more modules as a set of logic instructions stored in a machine- or computer-readable storage medium such as RAM, ROM, programmable ROM (PROM), firmware, etc., to be executed by a processor or computing device. For example, computer program code to carry out the operations of the components may be written in any combination of one or more operating system (OS) applicable/appropriate programming languages, including an object-oriented programming language such as PYTHON, PERL, JAVA, SMALLTALK, C++, C#, VHDL, Verilog, System C or the like and conventional procedural programming languages, such as the “C” programming language or similar programming languages. For example, the NAND media, other persistent storage media, or other system memory may store a set of instructions (e.g., that may be firmware instructions) that when executed by the processor 31 cause the system 30 to implement one or more components, features, or aspects of the system 30 (e.g., setting the adjustable trim voltage value, monitoring the voltage(s), turning the negative charge pump on/off, etc.).

An example NAND flash memory array may include multiple NAND memory cells arranged in columns, such as 3D NAND series strings. In one example, the memory cell includes a transistor with a replacement gate. A cell with a replacement gate typically has a low resistance gate (e.g., a tungsten gate) and a charge trap layer between the gate and the channel where charge is trapped or stored to represent one or more bit values. In another example, a memory cell can include a transistor with a floating gate (e.g., a high resistance poly gate) that stores charge indicative of one or more bit values. Other architectures are also possible. In the series strings, drain regions of cells are (with the exception of the top cell) coupled to a source region of another cell.

The NAND flash memory array also includes wordlines (WLs). The WLs can span across multiple series strings (e.g., a WL may be coupled to one memory cell of each series string) and are connected to the control gates of each memory cell of a row of the array and used to bias the control gates of the memory cells in the row. The bitlines (BLs) are each coupled to a series string by a drain select gate and sensing circuitry that detects the state of each cell by sensing voltage or current on a particular BL.

Multiple series strings of the memory cells are coupled to a source line by a source select gate and to an individual BL by a drain select gate. The source select gates are controlled by a source select gate control line and the drain select gates are controlled by a drain select gate control line.

In some examples, each memory cell can be programmed according to various encoding schemes such as SLC (single level cell), MLC (multi-level cell) TLC (triple level cell), QLC (quad level cell), or other encoding scheme. Each cell's threshold voltage (Vt) is indicative of the data that is stored in the cell.

In one example, a cell state that is set to store multiple bits may form a part of multiple different pages, with each bit of the cell corresponding to a distinct page. For example, for a cell that is to enter a state to store two (2) bits (e.g., using an MLC encoding scheme), one bit may correspond to an Upper Page (UP) and the other bit may correspond to a Lower Page (LP). For a cell that is to enter a state to store three (3) bits (e.g., using a TLC encoding scheme), one bit may correspond to an LP, one bit may correspond to a UP, and the other bit may correspond to an Extra Page (XP). For a cell that is to store four (4) bits (e.g., using a QLC encoding scheme), one bit may correspond to an LP, another bit may correspond to a UP, another bit may correspond to an XP, and the final bit may correspond to a Top Page (TP). Each page (e.g., LP, UP, XP, or TP) may include an aggregation of corresponding bits stored by a plurality of different cells of a WL.

A programming sequence for a group of cells may include programming of all of the intended pages into the group of cells. A programming sequence may include one or more programming passes. A programming pass (that may include one or more programming loops) may program one or more pages. A programming pass may include the application of one or more effective program voltages to cells to be programmed followed by the application of one or more verify voltages to these cells in order to determine which cells have finished programming (subsequent programming passes generally will not apply an effective program voltage and/or a verify voltage to the cells that have finished programming). The application of an effective program voltage to a cell may include changing the voltage difference between a control gate and a channel of the cell in order to change the threshold voltage of the cell. Accordingly, a voltage of a WL (coupled to the control gate of the target cell) and/or a channel of the cell may be set in order to effectuate application of an effective program voltage. As a program voltage is commonly used to refer to a voltage applied to a WL, the effective program voltage can be the voltage difference between a control gate and channel of a cell (that in instances where the channel is held at 0 V can be synonymous with a program voltage).

In one example, a controller for a non-volatile memory device includes input/output (I/O) interface circuitry to receive requests from a processor to access a non-volatile memory die, and control logic to generate commands in response to the requests from the processor, each of the commands to access one of multiple planes of the 3D memory die, queue the commands in separate queues for each of the planes based on a target plane of each of the commands, issue the commands to their target planes independent of other planes' status, and track completion status of the commands independently for each plane.

In one example, an article of manufacture including a computer readable storage medium having content stored thereon that when accessed causes processing circuitry to execute operations to perform a method described herein. For example, a method can include issuing, from a controller, a command to a 3D NAND die, the die including multiple planes, the command to target a first plane of the die, issuing a second command to the 3D NAND die to target a second plane while the first plane is busy, and tracking completion of both the first and second commands by polling status of the first plane and the second plane. In one example, a method includes receiving, at a 3D NAND die, a first command from a controller to target a first plane of the 3D NAND die, starting to service the first command, receiving a second command from the controller to target a second plane of the 3D NAND die while the first plane is busy, and starting to service the second command independent of a status of the first plane. Any of the examples herein describing operation at a plane-level can also apply to a group-level. In one example, an apparatus includes a non-volatile memory die (e.g., a 3D NAND die) including multiple groups of memory cells. In one such example, the die includes multiple planes of memory cells, the multiple planes grouped into groups, each of the groups including two or more planes. In one such example, control logic is to generate commands in response to requests from a host, each of the commands to access one of the groups, queue the commands in separate queues for each of the groups based on a target group of each of the commands, issue the commands to their target groups independent of other groups' status, and track completion status of the commands independently for each group.

An example NAND flash memory array may include multiple NAND memory cells arranged in columns, such as 3D NAND series strings. In one example, the memory cell includes a transistor with a replacement gate. A cell with a replacement gate typically has a low resistance gate (e.g., a tungsten gate) and a charge trap layer between the gate and the channel where charge is trapped or stored to represent one or more bit values. In another example, a memory cell can include a transistor with a floating gate (e.g., a high resistance poly gate) that stores charge indicative of one or more bit values. Other architectures are also possible. In the series strings, drain regions of cells are (with the exception of the top cell) coupled to a source region of another cell.

The NAND flash memory array also includes wordlines (WLs). The WLs can span across multiple series strings (e.g., a WL may be coupled to one memory cell of each series string) and are connected to the control gates of each memory cell of a row of the array and used to bias the control gates of the memory cells in the row. The bitlines (BLs) are each coupled to a series string by a drain select gate and sensing circuitry that detects the state of each cell by sensing voltage or current on a particular BL.

Multiple series strings of the memory cells are coupled to a source line by a source select gate and to an individual BL by a drain select gate. The source select gates are controlled by a source select gate control line and the drain select gates are controlled by a drain select gate control line.

In some examples, each memory cell can be programmed according to various encoding schemes such as SLC (single level cell), MLC (multi-level cell) TLC (triple level cell), QLC (quad level cell), or other encoding scheme. Each cell's threshold voltage (Vt) is indicative of the data that is stored in the cell.

In one example, a cell state that is set to store multiple bits may form a part of multiple different pages, with each bit of the cell corresponding to a distinct page. For example, for a cell that is to enter a state to store two (2) bits (e.g., using an MLC encoding scheme), one bit may correspond to an Upper Page (UP) and the other bit may correspond to a Lower Page (LP). For a cell that is to enter a state to store three (3) bits (e.g., using a TLC encoding scheme), one bit may correspond to an LP, one bit may correspond to a UP, and the other bit may correspond to an Extra Page (XP). For a cell that is to store four (4) bits (e.g., using a QLC encoding scheme), one bit may correspond to an LP, another bit may correspond to a UP, another bit may correspond to an XP, and the final bit may correspond to a Top Page (TP). Each page (e.g., LP, UP, XP, or TP) may include an aggregation of corresponding bits stored by a plurality of different cells of a WL.

A programming sequence for a group of cells may include programming of all of the intended pages into the group of cells. A programming sequence may include one or more programming passes. A programming pass (that may include one or more programming loops) may program one or more pages. A programming pass may include the application of one or more effective program voltages to cells to be programmed followed by the application of one or more verify voltages to these cells in order to determine which cells have finished programming (subsequent programming passes generally will not apply an effective program voltage and/or a verify voltage to the cells that have finished programming). The application of an effective program voltage to a cell may include changing the voltage difference between a control gate and a channel of the cell in order to change the threshold voltage of the cell. Accordingly, a voltage of a WL (coupled to the control gate of the target cell) and/or a channel of the cell may be set in order to effectuate application of an effective program voltage. As a program voltage is commonly used to refer to a voltage applied to a WL, the effective program voltage can be the voltage difference between a control gate and channel of a cell (that in instances where the channel is held at 0 V can be synonymous with a program voltage).

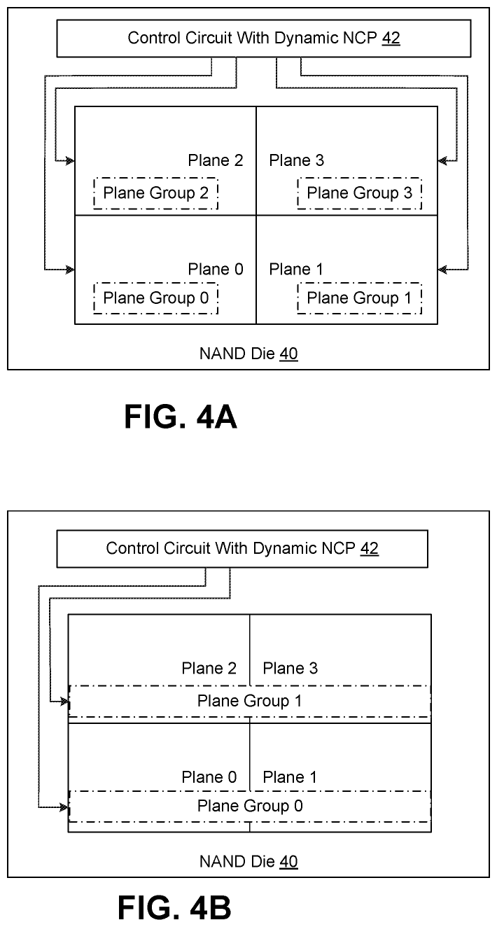

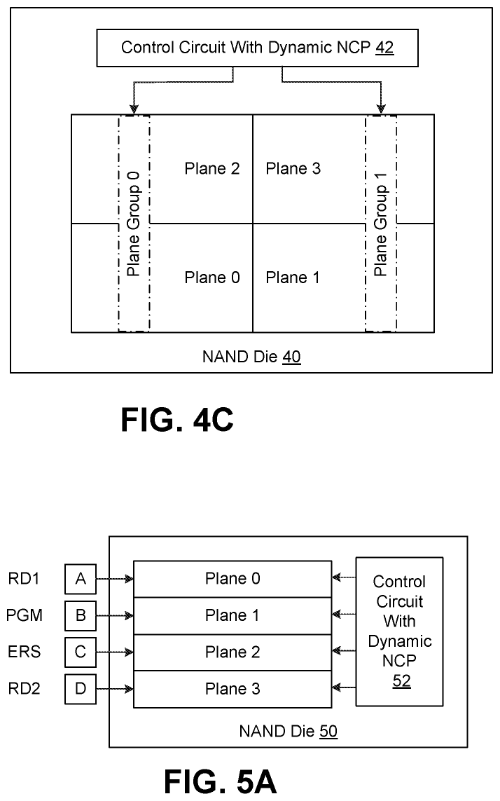

FIGS. 4A to 4C depict example organizations of a NAND flash memory array in which independent NAND memory operations can be implemented. A suitable NAND die may include at least two physical or logical planes further organized in any suitable arrangement of two or more plane groups. In the illustrated example, the NAND die 40 includes four planes (Plane 0 through Plane 3) and a control circuit 42 (e.g., with dynamic negative charge pump (NCP) technology as described herein) to provide suitable voltages to each plane or plane group. In FIG. 4A, the NAND die 40 includes four plane groups (Plane Group 0 through Plane Group 3) with each of the four planes as its own plane group, and the control circuit 42 provides suitable voltages to each of the four plane groups. In FIG. 4B, the NAND die 40 includes two plane groups with Plane 0 and Plane 1 in Plane Group 0, and Plane 2 and Plane 3 in Plane Group 1, and the control circuit 42 provides suitable voltages to each of the two plane groups. In FIG. 4C, the NAND die 40 includes two plane groups with Plane 0 and Plane 2 in Plane Group 0, and Plane 1 and Plane 3 in Plane Group 1, and the control circuit 42 provides suitable voltages to each of the two plane groups. Advantageously, by turning off the appropriate negative charge pumps when the corresponding sense operations are in a positive range (e.g., as compared to corresponding trim thresholds), some examples reduce energy consumption and improve energy-per-bit for the NAND die 40.

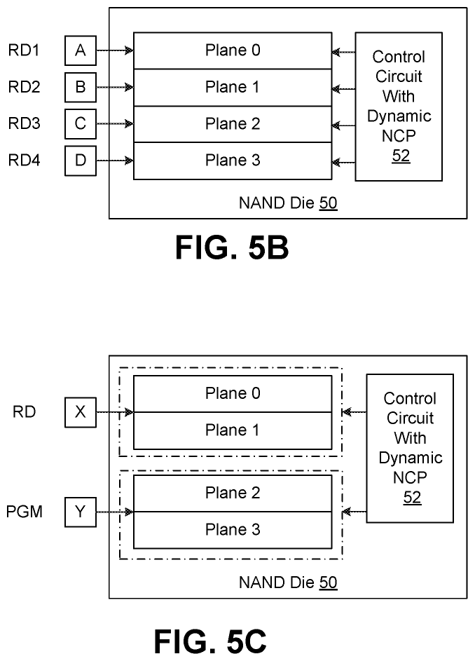

Some NAND devices may support independent multi-plane operations that enable independent and concurrent operations per plane. Separate state machines for each plane enable application of different bias voltages for each plane to independently and concurrently service requests. FIGS. 5A-5C illustrate examples of independent multi-plane operations. FIG. 5A illustrates an example of a fully independent multi-plane array operation (IMPO). FIG. 5B illustrates an example of an independent multi-plane read operation (IMPRO). FIG. 5C illustrates another example of an independent multi-plane array operation (eIMPRO or enhanced IMPO (eIMPO)). In all of FIGS. 5A-5C, the NAND die 50 includes four planes (plane 0, plane 1, plane 2, and plane 3) and a control circuit 52 (e.g., e.g., with dynamic NCP technology as described herein) to provide suitable voltages to each plane or plane group. Although the examples in FIGS. 5A-5C describe four planes per NAND die, a NAND die may be divided into fewer or more than four planes (e.g., 1, 2, 8, etc.). Advantageously, by turning off the appropriate negative charge pumps when the corresponding sense operations are in a positive range (e.g., as compared to corresponding trim thresholds), some examples reduce energy consumption and improve energy-per-bit for the NAND die 50.

Referring to FIG. 5A, all NAND array commands are allowed independently on the plane level, enabling significant performance improvements. An array command is a command that causes an array operation, such as programming data to the array, reading data from the array, erasing a block, or other operations on the array. FIG. 5A illustrates an example where read commands (commands A and D) are sent to plane 0 and plane 3, a program command (command B) is sent to plane 1, and an erase command (command C) is sent to plane 2. Each plane can receive and service a different array command, and the commands can be sent and completed at different times. Non-array commands (e.g., reset, timing mode changes, etc.) can be maintained as die-level commands.

Referring to FIG. 5B, read operations (and some supporting commands for reads) are allowed independently on the plane level. As illustrated, four reads (operations A, B, C, and D) are sent to planes 0, 1, 2, and 3. In this example, other operations, such as program and erase, are still die-level operations. Supporting commands for read, such as read status and read column enhanced may also be plane-level commands.

FIG. 5C illustrates an “enhanced” version of independent plane-level operations in which groups of planes can allow one independent array operation amongst them. In this example, only reads or all array-operations can be sent to groups of planes independently. In one example, planes are grouped in pairs (e.g., each group includes two planes). Other implementations may include more than two planes in a group, or may group the array in other ways.

In some examples, the NAND commands may be split into two groups: 1) plane/group level commands, and 2) die-level commands. An internal controller (e.g., ASIC) and/or firmware may be aware of the distinction between plane-level and die-level commands and may handle the two types of commands differently. For example, a “controller queue” and a “responder queue” per plane/group level are implemented in the ASIC and/or firmware to handle the die-level and plane-level commands.

Examples for independent and concurrent array operations follow. In one example, an apparatus includes a 3D NAND die including multiple planes of memory cells and control logic. The control logic can include circuitry, firmware, software, or a combination. Some or all of the control logic can be implemented by an internal controller, such as an ASIC. The control logic is to generate commands in response to requests from a host, each of the commands to access one of the planes, queue the commands in separate queues for each of the planes based on a target plane of each of the commands, issue the commands to their target planes independent of other planes' status, and track completion status of the commands independently for each plane. In one example, the control logic to send a command to its target plane is to independently generate bias voltages for each of the planes targeted by one of the commands In one example, the control logic is to issue a command to target one of the planes when another of the planes is busy. In one example, the control logic is to read data upon completion of a read command from one plane while another plane is busy servicing another read command.

In one example, the control logic to track completion status is to send a command to read status of a target plane, the 3D NAND die to return the status of the target plane on input/output (I/O) pins of the die. In one example, the command to read status of a plane includes one or more bits to specify a plane. In one example, the control logic is to send a command to modify settings of a plane without modification of settings of other planes, the settings including one or more of: WL voltage for array operation, BL voltage for array operation, program verify levels, read reference values, maximum WL bias value, and array operation timeout period. In one example, the control logic to queue the commands is to queue the commands in a die-level queue for the die, and route each of the commands from the die-level queue to plane-level queues based on the target plane of each of the commands.

In one example, the control logic is to generate a die-level command in response to a request from the queue and queue the die-level command in the die-level queue. In one such example, the control logic is to route the die-level command to one of the plane-level queues, and prevent execution of plane-level commands while the die-level command is serviced. In one example, the control logic to prevent execution of plane-level commands is to send placeholder commands to at least one of the plane-level queues to prevent execution of plane-level commands In one example, the control logic to prevent execution of plane-level commands is to prevent routing plane-level commands to the plane-level queues while the die-level command is serviced. In one example, the requests from the host are from a host processor, an accelerator, a memory controller, or a host operating system. In one example, the apparatus comprises a solid state drive (SSD) or a dual in-line memory module (DIMM).

In one example, a controller for a non-volatile memory device includes input/output (I/O) interface circuitry to receive requests from a processor to access a non-volatile memory die, and control logic to generate commands in response to the requests from the processor, each of the commands to access one of multiple planes of the 3D memory die, queue the commands in separate queues for each of the planes based on a target plane of each of the commands, issue the commands to their target planes independent of other planes' status, and track completion status of the commands independently for each plane.

In one example, an article of manufacture including a computer readable storage medium having content stored thereon that when accessed causes processing circuitry to execute operations to perform a method described herein. For example, a method can include issuing, from a controller, a command to a 3D NAND die, the die including multiple planes, the command to target a first plane of the die, issuing a second command to the 3D NAND die to target a second plane while the first plane is busy, and tracking completion of both the first and second commands by polling status of the first plane and the second plane. In one example, a method includes receiving, at a 3D NAND die, a first command from a controller to target a first plane of the 3D NAND die, starting to service the first command, receiving a second command from the controller to target a second plane of the 3D NAND die while the first plane is busy, and starting to service the second command independent of a status of the first plane. Any of the examples herein describing operation at a plane-level can also apply to a group-level. In one example, an apparatus includes a non-volatile memory die (e.g., a 3D NAND die) including multiple groups of memory cells. In one such example, the die includes multiple planes of memory cells, the multiple planes grouped into groups, each of the groups including two or more planes. In one such example, control logic is to generate commands in response to requests from a host, each of the commands to access one of the groups, queue the commands in separate queues for each of the groups based on a target group of each of the commands, issue the commands to their target groups independent of other groups' status, and track completion status of the commands independently for each group.

Thus, techniques described herein enable NAND to perform array operations independently and concurrently on the plane or group level. Note that although many examples refer to plane-level queues, commands, and state machines, the examples also apply to other groupings such as plane groups (e.g. as illustrated in FIGS. 4B, 4C, and 5C). For examples that utilize plane groups, there are separate state machines, commands, and queues for the plane groups.

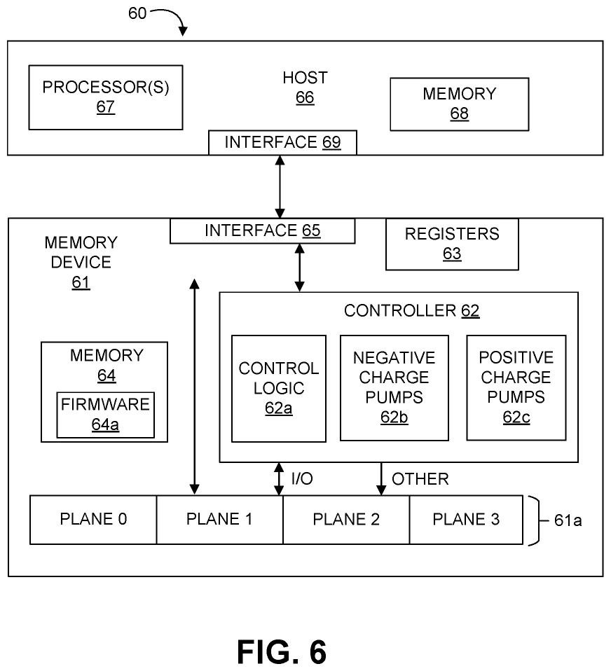

FIG. 6 depicts an example system 60. The system 60 includes a host 66 and a memory device 61. The host 66 and memory device 61 can be an example of a system 60 that exists within the confines of a computer's package (e.g., within a laptop/notebook, server, or other computer). In other examples, the memory device 61 may also be accessed via a larger network such as a local area network (e.g., an Ethernet network), or a wide area network (such as a wireless cellular network, the Internet, etc.). Such examples may be in compliance with a standard such as NVMe-oF (non-volatile memory express over fabrics). The host 66 includes one or more processors 67, memory 68, and other components that are omitted from the drawing for clarity.

The memory device 61 includes a memory medium 61a for storing data. Memory medium 61a can be a memory or storage medium that can store one or more bits in memory cells. In one example, the memory medium 61a includes one or more non-volatile memory die, each divided into multiple planes or groups. In some examples, the memory medium 61a can include block addressable memory devices, such as NAND technologies. In one example, the memory medium 61a includes a NAND flash memory array. The memory medium 61a can also include byte addressable non-volatile memory. Other technologies, such as some NOR flash memory, may be byte addressable for reads and/or writes, and block addressable for erases. The memory medium 61a can include memory devices that use chalcogenide phase change material (e.g., chalcogenide glass), multi-threshold level NAND flash memory, NOR flash memory, single or multi-level phase change memory (PCM), a resistive memory, nanowire memory, ferroelectric transistor random access memory (FeTRAM), magneto resistive random access memory (MRAM) memory that incorporates memristor technology, or spin transfer torque MRAM (STT-MRAM), or a combination of any of the above, or other memory types. Memory medium 61a can include a single-level cell (SLC) NAND storage device, a multi-level cell (MLC) NAND storage device, triple-level cell (TLC) NAND storage device, quad-level cell (QLC) storage device.

The memory device 61 can communicate with the host 66 using respective interfaces 65 and 69. In one example, the interface 69 is a part of a peripheral control hub (PCH). In the illustrated example, the controller 62 is coupled with a computing platform such as host 66 using the interface 65. In one example, the controller 62 is an ASIC (application specific integrated circuit). In one example, the interfaces are compliant with a standard such as PCI Express (PCIe), serial advanced technology attachment (ATA), a parallel ATA, universal serial bus (USB), and/or other interface protocol(s). The controller 62 can communicate with elements of the computing platform to read data from memory medium 61a or write data to memory medium 61a. Although in this example, the term “host” is referring to a system 60 with a processor (or other device sending requests to access data stored in a non-volatile memory) and an interface for communicating with the NAND (e.g., the host 66), some implementations may refer to the controller 62 as a “host” relative to the non-volatile memory medium 61a.

The controller 62 can be configured to receive requests from the host 66 and generate and perform commands concerning the use of memory medium 61a (e.g., to read data, write, or erase data). Other commands may include, for example, commands to read status, commands to change configuration settings, a reset command, etc. The controller 62 can be implemented with hardware (e.g., logic circuitry 62a), software, firmware, or a combination of hardware, software and firmware. Examples of logic circuitry 62a include dedicated hardwired logic circuitry (including, e.g., one or more state machine logic circuits), programmable logic circuitry (e.g., FPGA, PLA, etc.). In one example, logic circuitry 62a is designed to execute some form of program code such as SSD firmware (e.g., an embedded processor, embedded controller, etc.). The memory device 61 typically also includes memory 64 coupled to the logic circuitry 62a that can be used to cache NVM data and store firmware 64a executed by the controller 62. The term “control logic” can be used to refer to both logic circuitry, firmware, software, or a combination. For example, control logic can refer to the control logic 62a, firmware 64a, or both. Although firmware is illustrated as being stored in memory 64, firmware may also or alternatively be stored in the controller 62 and/or the memory die.

The controller 62 is coupled with the memory medium 61a to control or command the memory to cause operations to occur (e.g., read, program, erase, suspend, resume, and other operations). Communication between the memory medium 61a and the controller 62 may include the writing to and/or reading from specific registers (e.g., registers 63). Such registers may reside in the controller 62, in the memory medium 61a, or external to the controller 62 and the memory medium 61a. Registers or memory within the memory medium 61a may be reachable by the controller 62 by, e.g., an internal interface of the memory device 61 that exists between the controller 62 and memory medium 61a (e.g., an Open NAND Flash Interface (ONFI) interface, a proprietary interface, or other interface) to communicatively couple the controller 62 and memory medium 61a. Input/output (I/O) pins and signal lines communicatively couple the controller 62 with the memory medium 61a to enable the transmission of read and write data between the controller 62 and the memory medium 61a. The I/O pins may also be used to transmit other data, such as status information of the dies or planes of memory medium 61a. The memory medium 61a can also include other pins such as command pins (e.g., command latch enable (CLE), address latch enable (ALE), chip enable (CE #), read enable (RE #), and write enable (WE #)), power and ground pins (e.g., Vcc, Vss, etc.). In one example, the memory medium includes a pin for indicating ready/busy status. However, in implementations with many memory dies in a package, it is often impractical to use a dedicated ready/busy pin for each die. Instead, in some examples, status can be output on the I/O pins of the dies in response to a request to read status.

The controller 62 can be coupled to WLs of memory medium 61a to select one of the WLs, apply read voltages, apply program voltages combined with BL potential levels, or apply erase voltages. The controller 62 can be coupled to BLs of memory medium 61a to read data stored in the memory cells, determine a state of the memory cells during a program operation, and control potential levels of the BLs to promote or inhibit programming and erasing. Other circuitry can be used for applying selected read voltages and other signals to memory medium 61a.

As mentioned above, the memory medium 61a can include a NAND memory. A NAND dies of the NAND memory may have multiple planes per die. In some examples, a plane includes multiple memory cells that may be grouped into blocks. A block is typically the smallest erasable entity in a NAND flash die. In one example, a block includes a number of cells that are coupled to the same BL. A block includes one or multiple pages of cells. The size of the page can vary depending on implementation. In one example, a page has a size of 16 kilobytes (KB). Page sizes of less or more than 16 KB are also possible (e.g., 512 B, 2 KB, 4 KB, etc.).

In accordance with some examples, the controller 62 further includes or is communicatively coupled to negative charge pumps 62b and positive charge pumps 62c and the control logic 62a may provide dynamic configuration of the negative charge pumps 62b (e.g., including one or more features of any of the examples described herein). In some examples, the control logic 62a may actively monitor various sense voltages and then adjusts a negative charge pump responsible to supply the negative WL voltage during the IMPRO and program verify IMPO operations. In some examples, one or more trim threshold voltages may be stored in the registers 63. The control logic 62a may be configured set the trim threshold voltages values stored in the registers 63 to indicate whether or not the negative charge pump is needed for various IMPO/IMPRO(s). The trim threshold voltage values stored in the registers may be updated as needed.

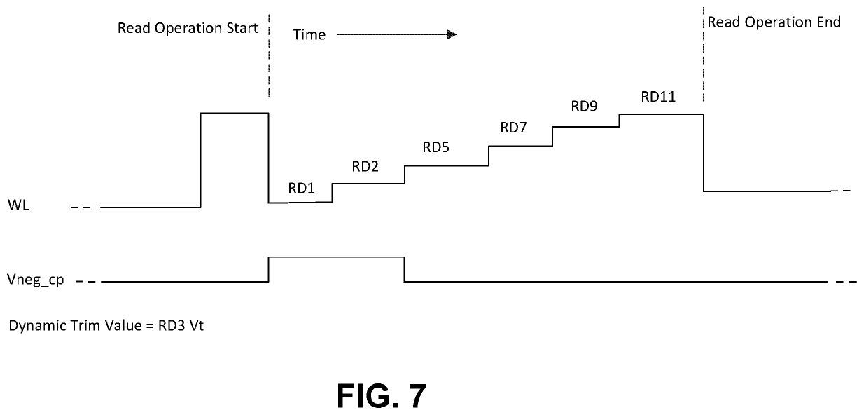

FIG. 7 shows an example of an illustrative timing diagram for a dynamic negative charge pump configuration for an IMPRO operation. A WL voltage and a corresponding negative voltage from a negative charge pump (Vneg_cp) may be generated from a control circuit with a dynamic Vneg_cp configuration. In a conventional circuit, the negative charge pump that provides Vneg_cp is kept ON during the entire IMPRO operation (e.g., from the vertical dashed line labeled as “Read Operation Start” through the vertical dashed line labeled as “Read Operation End”) regardless of the Vt-level being sensed, consuming energy and degrading the energy-per-bit. With an example of dynamic negative charge pump configuration technology, the current Vt-level being sensed is compared against an adjustable dynamic trim value. In the example of FIG. 7, the dynamic trim value is set to the lowest positive threshold voltage that will govern the turning on/off of the negative charge pump. For a QLC read if L0 to L2 Vt levels are negative and L3 to L15 Vt levels are positive, for example, then the dynamic trim value is set to Vt level of L3. Whenever the Vt level being sensed is greater than the set dynamic trim value, Vneg_cp is turned off, advantageously reducing the energy consumption and improving the energy-per-bit for IMPRO operation. FIG. 7 shows an example where the dynamic trim value is set to the Vt of an L3 read operation (RD3). Vneg_cp is turned on at the start of the read operation that starts at L1, stays on when the Vt moves to L2, and then turns off when the Vt moves to L5 (e.g., when Vt becomes greater than the Vt of L3).

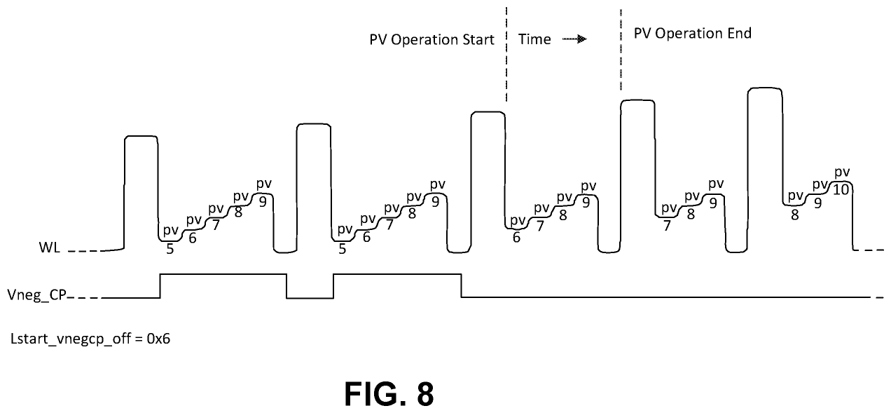

FIG. 8 shows another example of an illustrative timing diagram for a dynamic negative charge pump configuration for a program verify (PV) operation. A WL voltage and a corresponding negative voltage from a negative charge pump (Vneg_cp) may be generated from a control circuit with a dynamic Vneg_cp configuration. In a conventional system, the negative charge pump that provides Vneg_cp is always kept ON during program-verify (e.g., from the vertical dashed line labeled as “PV Operation Start” through the vertical dashed line labeled as “PV Operation End”) regardless of the Vt-Level being verified and turned OFF during the program-pulse, consuming energy and degrading the energy-per-bit. With an example of dynamic negative charge pump configuration technology, the current Vt-Level being verified is compared against an adjustable trim value that is set to the Vt-Level with a least positive voltage. For example, for a QLC program if L0 to L5 have a negative target-Vt and L6 to L15 have a positive target-Vt then the adjustable trim value is set to correspond to the Vt of L6.

In this example, a variable “Lstart_vnegcp_off” trim is set to 0x06 to indicate voltage level six (e.g., instead of the numeric value of the voltage level itself). With the dynamic Vneg_cp configuration feature enabled (e.g., per a configuration setting), the NAND controller compares the current Vt-level being verified with the trim level stored in the Lstart_vnegcp_off variable and if current verify Vt-Level is equal or greater than the stored trim level then the negative charge pump that provides Vneg_cp is shut-off, advantageously reducing the energy usage and improving the energy-per-bit. In some examples (e.g., for a program verify operation), the negative charge pump is not turned off in the middle of the operation. Instead, the NAND controller checks the current Vt-level being verified at the start of the PV operation and turns of the negative charge pump at the start of the PV operation if the current Vt-level is greater than or equal to the stored trim level. Otherwise, the negative charge pump remains on for the PV operation even if the Vt-level goes above the stored trim level during the PV operation.

The technology discussed herein may be provided in various computing systems (e.g., including a non-mobile computing device such as a desktop, workstation, server, rack system, etc., a mobile computing device such as a smartphone, tablet, Ultra-Mobile Personal Computer (UMPC), laptop computer, ULTRABOOK computing device, smart watch, smart glasses, smart bracelet, etc., and/or a client/edge device such as an Internet-of-Things (IoT) device (e.g., a sensor, a camera, etc.)).

### ADDITIONAL NOTES AND EXAMPLES

Example 1 includes an apparatus, comprising NAND memory, and circuitry coupled to the NAND memory to monitor a sense voltage for an operation associated with a wordline of the NAND memory, and adjust a negative charge pump for the wordline prior to completion of the operation based on the monitored sense voltage.

Example 2 includes the apparatus of Example 1, wherein the circuitry is further to adjust the negative charge pump for the wordline based on a comparison of the monitored sense voltage and a trim threshold voltage value.

Example 3 includes the apparatus of Example 2, wherein the circuitry is further to turn on the negative charge pump if the monitored sense voltage is less than the trim threshold voltage value, and turn off the negative charge pump when the monitored sense voltage is greater than or equal to the trim threshold voltage value.

Example 4 includes the apparatus of any of Examples 1 to 3, wherein the circuitry is further to compare the monitored sense voltage for a read operation against an adjustable trim voltage value, turn on the negative charge pump at a start of the read operation if the monitored sense voltage is less than the adjustable trim voltage value, and turn off the negative charge pump prior to completion of the read operation if the monitored sense voltage is greater than or equal to the adjustable trim voltage value.

Example 5 includes the apparatus of Example 4, wherein the circuitry is further to adjust the adjustable trim voltage value based on a lowest positive threshold voltage (Vt) level for the read operation.

Example 6 includes the apparatus of any of Examples 1 to 5, wherein the circuitry is further to compare the monitored sense voltage at a start of a program verify operation against an adjustable trim voltage value, turn on the negative charge pump if the monitored sense voltage at the start of the program verify operation is less than the adjustable trim voltage value, and turn off the negative charge pump if the monitored sense voltage at the start of the program verify operation is greater than or equal to the adjustable trim voltage value.

Example 7 includes the apparatus of Example 7, wherein the circuitry is further to adjust the adjustable trim voltage value based on a lowest positive target threshold voltage (Vt) level for the program verify operation.

Example 8 includes the apparatus of any of Examples 1 to 7, wherein the NAND memory comprises three-dimensional NAND memory.

Example 9 includes a memory device, comprising NAND media, and a controller coupled to the NAND media to set a trim threshold voltage value, monitor a voltage for a sense operation associated with a wordline of the NAND media, and turn a negative charge pump for the sense operation one of on and off based on a comparison of the monitored voltage and the trim threshold voltage value.

Example 10 includes the memory device of Example 9, wherein the controller is further to turn on the negative charge pump if the monitored voltage is less than the trim threshold voltage value, and turn off the negative charge pump when the monitored sense voltage is greater than or equal to the trim threshold voltage value.

Example 11 includes the memory device of any of Examples 9 to 10, wherein the controller is further to set the trim threshold voltage value for a read operation based on a lowest positive threshold voltage (Vt) level for the read operation.

Example 12 includes the memory device of Example 11, wherein the controller is further to turn on the negative charge pump at a start of the read operation if the monitored voltage is less than the trim threshold voltage value, and turn off the negative charge pump prior to completion of the read operation if the monitored voltage is greater than or equal to the trim threshold voltage value.

Example 13 includes the memory device of any of Examples 9 to 12, wherein the controller is further to set the trim threshold voltage value based on a lowest positive target threshold voltage (Vt) level for a program verify operation.

Example 14 includes the memory device of Example 13, wherein the controller is further to turn on the negative charge pump if the monitored voltage at a start of the program verify operation is less than the trim threshold voltage value, and turn off the negative charge pump if the monitored voltage at the start of the program verify operation is greater than or equal to the trim threshold voltage value.

Example 15 includes the memory device of any of Examples 9 to 14, wherein the NAND media comprises three-dimensional NAND media.

Example 16 includes a system, comprising a processor, and a three-dimensional (3D) NAND memory device coupled to the processor, the 3D NAND memory device comprising 3D NAND media, a plurality of positive charge pumps respectively coupled to wordlines of the 3D NAND media, a plurality of negative charge pumps respectively coupled to wordlines of the 3D NAND media, and a controller to control access to the NAND media, wherein the controller is further to set an adjustable trim voltage value, monitor a voltage for a sense operation associated with a wordline of the 3D NAND media, and turn a negative charge pump for the sense operation one of on and off based on a comparison of the monitored voltage and the adjustable trim voltage value.

Example 17 includes the system of Example 16, wherein the controller is further to turn on the negative charge pump if the monitored voltage is less than the adjustable trim voltage value, and turn off the negative charge pump when the monitored sense voltage is greater than or equal to the adjustable trim voltage value.

Example 18 includes the system of any of Examples 16 to 17, wherein the controller is further to set the trim threshold voltage value for a read operation based on a lowest positive threshold voltage (Vt) level for the read operation.

Example 19 includes the system of Example 18, wherein the controller is further to turn on the negative charge pump at a start of the read operation if the monitored voltage is less than the adjustable trim voltage value, and turn off the negative charge pump prior to completion of the read operation if the monitored voltage is greater than or equal to the adjustable trim voltage value.

Example 20 includes the system of any of Examples 16 to 19, wherein the controller is further to set the adjustable trim voltage value based on a lowest positive target threshold voltage (Vt) level for a program verify operation.

Example 21 includes the system of Example 20, wherein the controller is further to turn on the negative charge pump if the monitored voltage at a start of the program verify operation is less than the adjustable trim voltage value, and turn off the negative charge pump if the monitored voltage at the start of the program verify operation is greater than or equal to the adjustable trim voltage value.

Example 22 includes a method, comprising monitoring information related to a voltage for a sense operation associated with a wordline of a NAND memory, and adjusting a negative charge pump for the wordline prior to completion of the operation based on the monitored information.

Example 23 includes the method of Example 22, further comprising comparing the information related to the monitored sense voltage and information indicated by a trim threshold value, and adjusting the negative charge pump for the wordline based on the comparison.

Example 24 includes the method of Example 23, further comprising turning on the negative charge pump if the comparison indicates that a sense voltage is less than a voltage that corresponds to the trim threshold value, and turning off the negative charge pump if the comparison indicates that a sense voltage is greater than or equal to the voltage that corresponds to the trim threshold value.

Example 25 includes the method of any of Examples 22 to 24, further comprising comparing the monitored sense voltage for a read operation against an adjustable trim voltage value, turning on the negative charge pump at a start of the read operation if the monitored sense voltage is less than the adjustable trim voltage value, and turning off the negative charge pump prior to completion of the read operation if the monitored sense voltage is greater than or equal to the adjustable trim voltage value.

Example 26 includes the method of Example 25, further comprising adjusting the adjustable trim voltage value based on a lowest positive threshold voltage (Vt) level for the read operation.

Example 27 includes the method of any of Examples 22 to 26, further comprising comparing the monitored sense voltage at a start of a program verify operation against an adjustable trim voltage value, turning on the negative charge pump if the monitored sense voltage at the start of the program verify operation is less than the adjustable trim value, and turning off the negative charge pump if the monitored sense voltage at the start of the program verify operation is greater than or equal to the adjustable trim value.

Example 28 includes the method of Example 27, further comprising adjusting the adjustable trim value based on a lowest positive target threshold voltage (Vt) level for the program verify operation.

Example 29 includes the method of any of Examples 22 to 28, wherein the NAND memory comprises three-dimensional NAND memory.

Example 30 includes at least one non-transitory one machine readable medium comprising a plurality of instructions that, in response to being executed on a computing device, cause the computing device to perform the method of any of Examples 22 to 29.

Example 31 includes an apparatus, comprising means for monitoring information related to a voltage for a sense operation associated with a wordline of a NAND memory, and means for adjusting a negative charge pump for the wordline prior to completion of the operation based on the monitored information.

Example 32 includes the apparatus of Example 31, further comprising means for comparing the information related to the monitored sense voltage and information indicated by a trim threshold value, and means for adjusting the negative charge pump for the wordline based on the comparison.

Example 33 includes the apparatus of Example 32, further comprising means for turning on the negative charge pump if the comparison indicates that a sense voltage is less than a voltage that corresponds to the trim threshold value, and means for turning off the negative charge pump if the comparison indicates that a sense voltage is greater than or equal to the voltage that corresponds to the trim threshold value.

Example 34 includes the apparatus of any of Examples 31 to 33, further comprising means for comparing the monitored sense voltage for a read operation against an adjustable trim voltage value, means for turning on the negative charge pump at a start of the read operation if the monitored sense voltage is less than the adjustable trim voltage value, and means for turning off the negative charge pump prior to completion of the read operation if the monitored sense voltage is greater than or equal to the adjustable trim voltage value.

Example 35 includes the apparatus of Example 34, further comprising means for adjusting the adjustable trim voltage value based on a lowest positive threshold voltage (Vt) level for the read operation.

Example 36 includes the apparatus of any of Examples 31 to 35, further comprising means for comparing the monitored sense voltage at a start of a program verify operation against an adjustable trim voltage value, means for turning on the negative charge pump if the monitored sense voltage at the start of the program verify operation is less than the adjustable trim value, and means for turning off the negative charge pump if the monitored sense voltage at the start of the program verify operation is greater than or equal to the adjustable trim value.

Example 37 includes the apparatus of Example 36, further comprising means for adjusting the adjustable trim value based on a lowest positive target threshold voltage (Vt) level for the program verify operation.

Example 38 includes the apparatus of any of Examples 31 to 37, wherein the NAND memory comprises three-dimensional NAND memory.

The term “coupled” may be used herein to refer to any type of relationship, direct or indirect, between the components in question, and may apply to electrical, mechanical, fluid, optical, electromagnetic, electromechanical or other connections. In addition, the terms “first”, “second”, etc. may be used herein only to facilitate discussion, and carry no particular temporal or chronological significance unless otherwise indicated.

As used in this application and in the claims, a list of items joined by the term “one or more of” may mean any combination of the listed terms. For example, the phrase “one or more of A, B, and C” and the phrase “one or more of A, B, or C” both may mean A; B; C; A and B; A and C; B and C; or A, B and C. Various components of the systems described herein may be implemented in software, firmware, and/or hardware and/or any combination thereof. For example, various components of the systems or devices discussed herein may be provided, at least in part, by hardware of a computing SoC such as may be found in a computing system such as, for example, a smart phone. Those skilled in the art may recognize that systems described herein may include additional components that have not been depicted in the corresponding figures. For example, the systems discussed herein may include additional components such as bit stream multiplexer or de-multiplexer modules and the like that have not been depicted in the interest of clarity.

While implementation of the example processes discussed herein may include the undertaking of all operations shown in the order illustrated, the present disclosure is not limited in this regard and, in various examples, implementation of the example processes herein may include only a subset of the operations shown, operations performed in a different order than illustrated, or additional operations.

In addition, any one or more of the operations discussed herein may be undertaken in response to instructions provided by one or more computer program products. Such program products may include signal bearing media providing instructions that, when executed by, for example, a processor, may provide the functionality described herein. The computer program products may be provided in any form of one or more machine-readable media. Thus, for example, a processor including one or more graphics processing unit(s) or processor core(s) may undertake one or more of the blocks of the example processes herein in response to program code and/or instructions or instruction sets conveyed to the processor by one or more machine-readable media. In general, a machine-readable medium may convey software in the form of program code and/or instructions or instruction sets that may cause any of the devices and/or systems described herein to implement at least portions of the operations discussed herein and/or any portions the devices, systems, or any module or component as discussed herein.

As used in any implementation described herein, the term “module” refers to any combination of software logic, firmware logic, hardware logic, and/or circuitry configured to provide the functionality described herein. The software may be embodied as a software package, code and/or instruction set or instructions, and “hardware”, as used in any implementation described herein, may include, for example, singly or in any combination, hardwired circuitry, programmable circuitry, state machine circuitry, fixed function circuitry, execution unit circuitry, and/or firmware that stores instructions executed by programmable circuitry. The modules may, collectively or individually, be embodied as circuitry that forms part of a larger system, for example, an integrated circuit (IC), system on-chip (SoC), and so forth.

Various examples may be implemented using hardware elements, software elements, or a combination of both. Examples of hardware elements may include processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), logic gates, registers, semiconductor device, chips, microchips, chip sets, and so forth. Examples of software may include software components, programs, applications, computer programs, application programs, system programs, machine programs, operating system software, middleware, firmware, software modules, routines, subroutines, functions, methods, procedures, software interfaces, application program interfaces (API), instruction sets, computing code, computer code, code segments, computer code segments, words, values, symbols, or any combination thereof. Determining whether an example is implemented using hardware elements and/or software elements may vary in accordance with any number of factors, such as desired computational rate, power levels, heat tolerances, processing cycle budget, input data rates, output data rates, memory resources, data bus speeds and other design or performance constraints.

One or more aspects of at least one example may be implemented by representative instructions stored on a machine-readable medium that represents various logic within the processor, that when read by a machine causes the machine to fabricate logic to perform the techniques described herein. Such representations, known as IP cores may be stored on a tangible, machine readable medium and supplied to various customers or manufacturing facilities to load into the fabrication machines that actually make the logic or processor.

While certain features set forth herein have been described with reference to various implementations, this description is not intended to be construed in a limiting sense. Hence, various modifications of the implementations described herein, as well as other implementations, that are apparent to persons skilled in the art to which the present disclosure pertains are deemed to lie within the spirit and scope of the present disclosure.

It will be recognized that the examples are not limited to the examples so described, but may be practiced with modification and alteration without departing from the scope of the appended claims. For example, the above examples may include specific combination of features. However, the above examples are not limited in this regard and, in various implementations, the above examples may include the undertaking only a subset of such features, undertaking a different order of such features, undertaking a different combination of such features, and/or undertaking additional features than those features explicitly listed. The scope of the examples should, therefore, be determined with reference to the appended claims, along with the full scope of equivalents to which such claims are entitled.

What is claimed is:

1. An apparatus, comprising:
NAND memory; and
circuitry coupled to the NAND memory to:
monitor a sense voltage for an operation associated with a wordline of the NAND memory, and
adjust a negative charge pump for the wordline prior to completion of the operation based on the monitored sense voltage.

2. The apparatus of claim 1, wherein the circuitry is further to:
adjust the negative charge pump for the wordline based on a comparison of the monitored sense voltage and a trim threshold voltage value.

3. The apparatus of claim 2, wherein the circuitry is further to:
turn on the negative charge pump if the monitored sense voltage is less than the trim threshold voltage value; and
turn off the negative charge pump when the monitored sense voltage is greater than or equal to the trim threshold voltage value.

4. The apparatus of claim 1, wherein the circuitry is further to:
compare the monitored sense voltage for a read operation against an adjustable trim voltage value;
turn on the negative charge pump at a start of the read operation if the monitored sense voltage is less than the adjustable trim voltage value; and
turn off the negative charge pump prior to completion of the read operation if the monitored sense voltage is greater than or equal to the adjustable trim voltage value.

5. The apparatus of claim 4, wherein the circuitry is further to:
adjust the adjustable trim voltage value based on a lowest positive threshold voltage (Vt) level for the read operation.

6. The apparatus of claim 1, wherein the circuitry is further to:
compare the monitored sense voltage at a start of a program verify operation against an adjustable trim voltage value;
turn on the negative charge pump if the monitored sense voltage at the start of the program verify operation is less than the adjustable trim voltage value; and
turn off the negative charge pump if the monitored sense voltage at the start of the program verify operation is greater than or equal to the adjustable trim voltage value.

7. The apparatus of claim 7, wherein the circuitry is further to:
adjust the adjustable trim voltage value based on a lowest positive target threshold voltage (Vt) level for the program verify operation.

8. The apparatus of claim 1, wherein the NAND memory comprises three-dimensional NAND memory.

9. A memory device, comprising:
NAND media; and
a controller coupled to the NAND media to:
set a trim threshold voltage value;
monitor a voltage for a sense operation associated with a wordline of the NAND media, and
turn a negative charge pump for the sense operation one of on and off based on a comparison of the monitored voltage and the trim threshold voltage value.

10. The memory device of claim 9, wherein the controller is further to:
turn on the negative charge pump if the monitored voltage is less than the trim threshold voltage value; and
turn off the negative charge pump when the monitored sense voltage is greater than or equal to the trim threshold voltage value.

11. The memory device of claim 9, wherein the controller is further to:
set the trim threshold voltage value for a read operation based on a lowest positive threshold voltage (Vt) level for the read operation.

12. The memory device of claim 11, wherein the controller is further to:
turn on the negative charge pump at a start of the read operation if the monitored voltage is less than the trim threshold voltage value; and
turn off the negative charge pump prior to completion of the read operation if the monitored voltage is greater than or equal to the trim threshold voltage value.

13. The memory device of claim 9, wherein the controller is further to:
set the trim threshold voltage value based on a lowest positive target threshold voltage (Vt) level for a program verify operation.

14. The memory device of claim 13, wherein the controller is further to:
turn on the negative charge pump if the monitored voltage at a start of the program verify operation is less than the trim threshold voltage value; and
turn off the negative charge pump if the monitored voltage at the start of the program verify operation is greater than or equal to the trim threshold voltage value.

15. A system, comprising:
a processor; and
a three-dimensional (3D) NAND memory device coupled to the processor, the 3D NAND memory device comprising:
3D NAND media,
a plurality of positive charge pumps respectively coupled to wordlines of the 3D NAND media,
a plurality of negative charge pumps respectively coupled to wordlines of the 3D NAND media, and
a controller to control access to the NAND media, wherein the controller is further to set an adjustable trim voltage value, monitor a voltage for a sense operation associated with a wordline of the 3D NAND media, and turn a negative charge pump for the sense operation one of on and off based on a comparison of the monitored voltage and the adjustable trim voltage value.

16. The system of claim 15, wherein the controller is further to:
turn on the negative charge pump if the monitored voltage is less than the adjustable trim voltage value; and
turn off the negative charge pump when the monitored sense voltage is greater than or equal to the adjustable trim voltage value.

17. The system of claim 15, wherein the controller is further to:
set the trim threshold voltage value for a read operation based on a lowest positive threshold voltage (Vt) level for the read operation.

18. The system of claim 17, wherein the controller is further to:
turn on the negative charge pump at a start of the read operation if the monitored voltage is less than the adjustable trim voltage value; and
turn off the negative charge pump prior to completion of the read operation if the monitored voltage is greater than or equal to the adjustable trim voltage value.

19. The system of claim 15, wherein the controller is further to:
set the adjustable trim voltage value based on a lowest positive target threshold voltage (Vt) level for a program verify operation.

20. The system of claim 19, wherein the controller is further to:
turn on the negative charge pump if the monitored voltage at a start of the program verify operation is less than the adjustable trim voltage value; and
turn off the negative charge pump if the monitored voltage at the start of the program verify operation is greater than or equal to the adjustable trim voltage value.
